(19) United States
(12) Patent Application Publication
(10) Pub. No.: US 2025/0205821 A1
(43) Pub. Date: Jun. 26, 2025

(54) PROCESSING METHOD OF SINGLE CRYSTAL MATERIAL AND PROCESSING OBJECT

(71) Applicants: GlobalWafers Co., Ltd., Hsinchu (TW); mRadian Femto Sources Co., Ltd., Hsinchu City (TW)

(72) Inventors: Chien Chung Lee, Hsinchu (TW); Bo-Kai Wang, Hsinchu (TW); Ying-Ru Shih, Hsinchu (TW)

(73) Assignees: GlobalWafers Co., Ltd., Hsinchu (TW); mRadian Femto Sources Co., Ltd., Hsinchu City (TW)

(21) Appl. No.: 19/000,723

(22) Filed: Dec. 24, 2024

Related U.S. Application Data
(60) Provisional application No. 63/614,900, filed on Dec. 26, 2023.

(51) Int. Cl. B23K 26/362; B23K 26/402; H10D 62/832

(52) U.S. Cl. CPC B23K 26/362; B23K 26/402; H10D 62/8325

(57) ABSTRACT

A processing method of a single crystal material includes following steps. A single crystal material is provide as an object to be modified. A first laser beam is irradiated on a first surface of the object to be modified, so as to form a modification layer inside the object to be modified. The first water column and a second laser beam transmitted in the first water column are synchronously impacted and irradiated on a first side surface of the object to be modified, so as to form a first notch on the first side surface, wherein the first notch corresponds to the modification layer. In addition, a processing object is also provided.

### CROSS-REFERENCE TO RELATED APPLICATION

This application claims the priority benefits of U.S. provisional application Ser. No. 63/614,900, filed on Dec. 26, 2023. The entirety of the above-mentioned patent application is hereby incorporated by reference herein and made a part of this specification.

### BACKGROUND

### Technical Field

The disclosure relates to a processing method and processing object of a single crystal material.

### Description of Related Art

A notable example of single crystal material that has great industrial application value and is difficult to cut mechanically is silicon carbide. Because silicon carbide single crystal wafers are suitable for high temperatures and high voltages, they can be used to make transistors and be applied in fields such as electric vehicles or power conversion. As far as the existing technology is concerned, diamond wires are generally used to cut silicon carbide ingot to obtain wafers. However, this method has a large kerf loss, with common loss values ranging from 150 microns to 300 microns.

In addition, the conventional technology also attempts to use pulse laser to modify the inner portion of single crystal material (for example, silicon or sapphire) in which laser light wavelengths can partially penetrate materials. After modification with laser light, since the modification layer is no longer the original single crystal structure, its bonding strength has dropped significantly compared with the single crystal material. The inner portion of the single crystal material can be modified using the aforementioned laser light (for example, femtosecond laser). However, after the inner portion of the single crystal material is modified, there is still a lack of a reliable way to separate the single crystal material.

### SUMMARY

This disclosure provides a processing method of a single crystal material, which can reduce the loss of the single crystal material.

This disclosure provides a processing object that can be easily manufactured.

The processing method of a single crystal material of this disclosure includes the following steps: providing a single crystal material as an object to be modified, wherein the object to be modified has a first surface, a second surface and a first side surface, the first surface is opposite to the second surface, and the first side surface is connected to the first surface and the second surface; rendering a first laser beam irradiate the first surface of the object to be modified to form a modification layer in an inner portion of the object to be modified, wherein the modification layer is located between the first surface and the second surface; and endering a first water column and a second laser beam transmitted in the first water column impact and irradiate the first side surface synchronously to form a first notch on the first side surface, wherein the first notch corresponds to the modification layer.

The processing object of this disclosure includes a base material. The base material includes a single crystal material. The base material has a first surface, a processing surface and a side surface, the processing surface is located opposite the first surface, and the side surface is connected to the first surface and the processing surface. The processing surface includes a first processing area and a second processing area. The first processing area is closer to the side surface than the second processing area. A surface roughness of the first processing area is smaller than a surface roughness of the second processing area.

In an embodiment of this disclosure, the processing object of this disclosure further includes: in a condition where the first notch exists, destroy the modification layer to separate a processing object from the object to be modified.

In an embodiment of this disclosure, the processing object of this disclosure further includes: before rendering the first water column and the second laser beam transmitted in the first water column to synchronously impact and irradiate the first side surface, fixing the object to be modified between a first transparent substrate and a second transparent substrate, wherein the first side surface of the object to be modified is exposed in an air gap between the first transparent substrate and the second transparent substrate.

In an embodiment of this disclosure, the first surface and the second surface of the object to be modified are respectively fixed on the first transparent substrate and the second transparent substrate through a first pyrolytic glue layer and a second pyrolytic adhesive layer.

In an embodiment of this disclosure, an adhesion of the first pyrolytic glue layer falls in

a range of 0.2 kg/inch˜0.8 kg/inch.

In an embodiment of this disclosure, a peeling force of the first pyrolytic glue layer falls in a range of 9 gf/inch˜15 gf/inch.

In an embodiment of this disclosure, a pyrolysis temperature of the first pyrolytic glue layer falls in the range of 90°˜130°.

In an embodiment of this disclosure, the modification layer is located on a reference plane, a propagation direction of the second laser beam is substantially parallel to the reference plane, a normal direction of the reference plane and a crystal axis direction of the object to be modified form an angle θ, and 0°<θ<90°.

In an embodiment of this disclosure, the object to be modified further includes a second

side surface connected to the first surface and the second surface, and is disposed next to the first side surface or opposite to the first side surface, the processing method of the single crystal material further includes: rendering the first water column and the second laser beam transmitted in the first water column impact and irradiate the second side surface synchronously to form a second notch on the second side surface, wherein the second notch corresponds to the modification layer and separates from the first notch by a distance.

In an embodiment of this disclosure, the object to be modified further includes a second side surface connected to the first surface and the second surface, and is disposed next to the first side surface or opposite to the first side surface, the processing method of the single crystal material further includes: rendering a second water column and a third laser beam transmitted in the second water column impact and irradiate the second side surface synchronously to form a second notch on the second side surface, wherein the second notch corresponds to the modification layer and separates from the first notch by a distance.

Based on the above, in the single crystal material processing method of an embodiment of this disclosure, first, the first laser beam is used to irradiate the first surface of an object to be modified, so as to form a modification layer on the inner portion of an object to be modified; then, the first water column and the second laser beam transmitted in in the first water column are used to simultaneously impact and irradiate the first side surface of an object to be modified to form a first notch on the first side surface; finally, with the first notch present, destroy the modification layer to separate the processing object from the object to be modified. In this way, the modification layer can be easily destroyed with a little external force, and the processing object can be separated from the object to be modified. In addition, compared with mechanical cutting, separating the processing object by destroying the modification layer results in less loss of single crystal material.

### BRIEF DESCRIPTION OF THE DRAWINGS

FIG. 1A to FIG. 1E are schematic three-dimensional views of the processing flow of a single crystal material according to an embodiment of this disclosure.

FIG. 2 is a schematic cross-sectional view of an object to be modified in FIG. 1B.

FIG. 3 is a partial top view and perspective view of an object to be modified in FIG. 1B.

FIG. 4 is a schematic cross-sectional view of the first transparent substrate, the first pyrolytic glue layer, the object to be modified, the second pyrolytic adhesive layer and the second transparent substrate according to an embodiment of this disclosure.

FIG. 5 is a schematic cross-sectional view of a processing object according to an embodiment of this disclosure.

FIG. 6A to FIG. 6D are schematic three-dimensional views of part of the processing flow of a single crystal material according to another embodiment of the present disclosure.

FIG. 7A to FIG. 7B are schematic three-dimensional views of part of the processing flow of a single crystal material according to another embodiment of the present disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

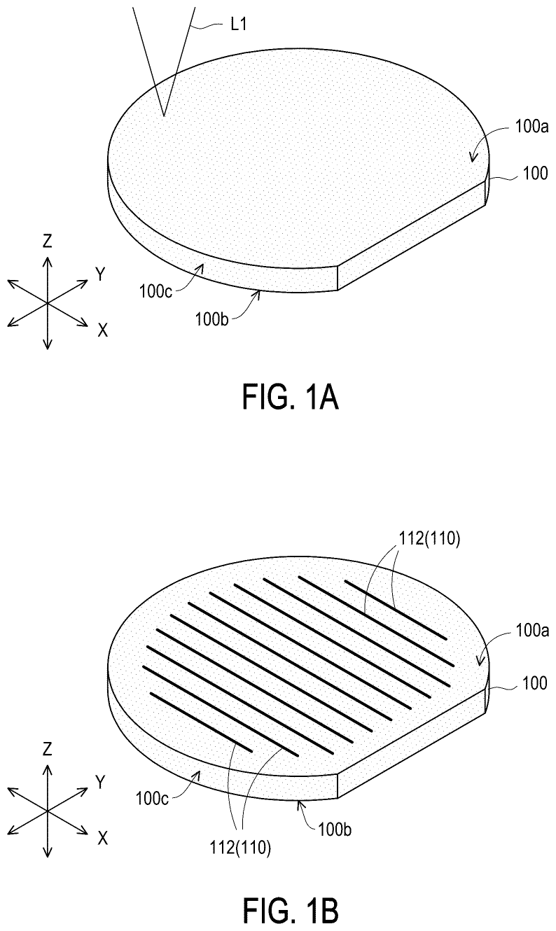

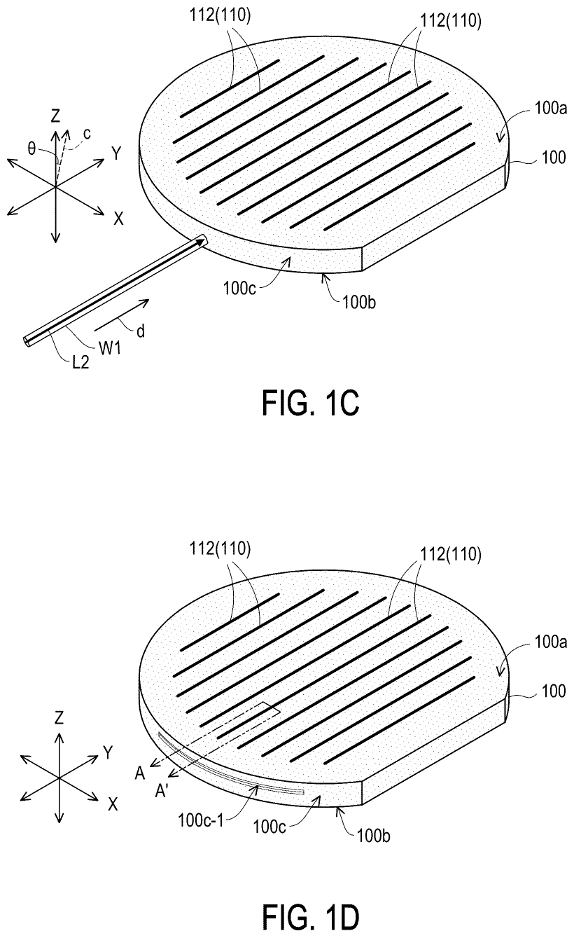

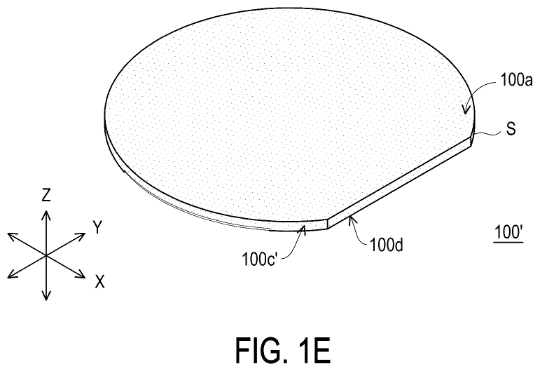

FIG. 1A to FIG. 1E are schematic three-dimensional views of the processing flow of a single crystal material according to an embodiment of this disclosure. For the sake of clarity, the directions X, Y and Z that are perpendicular to each other are drawn in each of the figures.

Referring to FIG. 1A, first, a single crystal material is provided as an object to be modified 100. For example, in some embodiments, the single crystal material may be a silicon carbide single crystal material. An object to be modified 100 has a first surface 100a, a second surface 100b and a first side surface 100c. The first surface 100a is opposite to the second surface 100b. The first side surface 100c is connected to the first surface 100a and the second surface 100b. In some embodiments, the first surface 100a may be a front surface of an object to be modified 100, the second surface 100b may be a back surface of an object to be modified 100, and the first side surface 100c may be a part of the peripheral surface of an object to be modified 100.

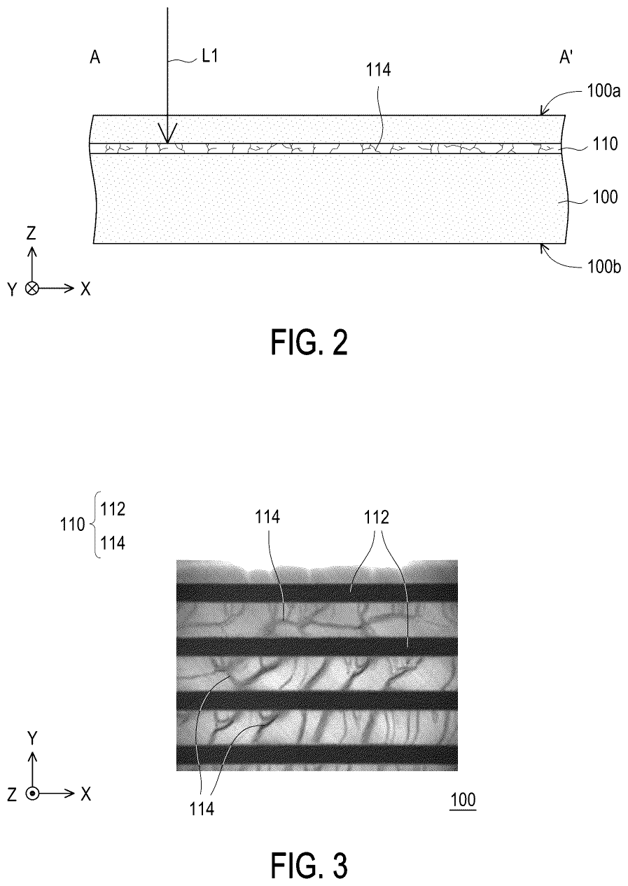

FIG. 2 is a schematic cross-sectional view of an object to be modified 100 in FIG. 1B. FIG. 3 is a partial top view and perspective view of an object to be modified 100 in FIG. 1B. FIG. 1B omits the illustration of the continuous crack 114 in FIG. 3. Please refer to FIGS. 1A, 1B, 2 and 3, next, a first laser beam L1 is irradiated onto the first surface 100a of the object to be modified 100, so as to form a modification layer 110 in an inner portion of the object to be modified 100, wherein the modification layer 110 is located between the first surface 100a and the second surface 100b.

For example, in some embodiments, the first laser beam L1 can be a femtosecond laser beam, and using the femtosecond laser beam to illuminate the first surface 100a can form processing traces in the inner portion of an object to be modified 100. In some embodiments, the processing traces may include multiple processing lines 112, the multiple processing lines 112 may extend in the direction X and be arranged in parallel in the direction Y, and continuous cracks 114 may exist between the multiple processing lines 112. In some embodiments, the modification layer 110 may include a plurality of processing lines 112 and a continuous crack 114 between the plurality of processing lines 112, wherein the plurality of processing lines 112 and the continuous crack 114 are substantially located on an XY reference plane where the direction X and the direction Y are located.

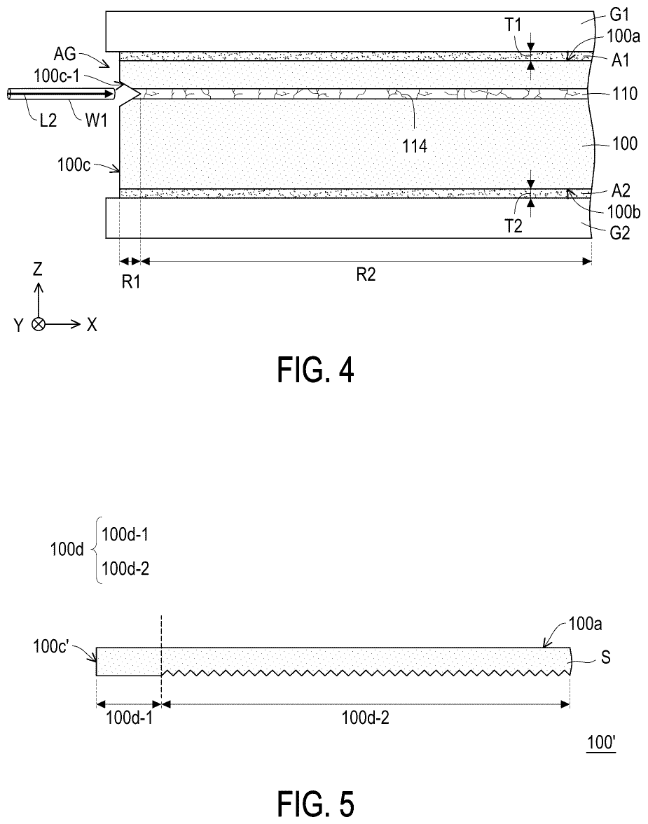

FIG. 4 is a schematic cross-sectional view of the first transparent substrate G1, the first pyrolytic glue layer A1, the object to be modified 100, the second pyrolytic adhesive layer A2 and the second transparent substrate G2 according to an embodiment of this disclosure. The cross-section of the object to be modified 100 in FIG. 4 corresponds to the cross-section line A-A′ in FIG. 1D. Referring to FIG. 1C, FIG. 1D and FIG. 4, then, render a first water column W1 and a second laser beam L2 transmitted in the first water column W1 synchronously impact and irradiate on the first side surface 100c, so as to form a first notch 100c-1 on the first side surface 100c of an object to be modified 100, wherein the first notch 100c-1 corresponds to the modification layer 110. Specifically, the impact and irradiation point of the first water column W1 and the second laser beam L2 is where the continuous crack 114 extends to the first side surface 100c, and the first notch 100c-1 and the continuous crack 114 may be actually located on the same XY reference plane. For example, in some embodiments, the size of the first notch 100c-1 may be (5 cm×3 mm)˜(5 cm×5 mm), but this disclosure is not limited to thereto. The first water column W1 and the second laser beam L2 form a water laser. Compared with traditional water jets, the water flow of the water laser is smaller, and the water pressure caused by the water laser on the object to be modified 100 is also lower, making it less likely to cause unnecessary damage to an object to be modified 100.

Referring to FIG. 1C, in some embodiments, the propagation direction d of the first water column W1 and the propagation direction d of the second laser beam L2 may not be parallel to the crystal axis direction c of the object to be modified 100 to improve the yield rate of subsequent separation of processing objects (i.e. splitting of processing objects). For example, in some embodiments, the modification layer 110 is located on the XY reference plane, and the propagation direction d of the first water column W1 and the second laser beam L2 may be substantially parallel to the XY reference plane where the directions X and Y are located, and a normal direction of the XY reference plane (i.e. the direction Z) and the crystal axis direction c may form an angle θ, and 0°<θ<90°. In some embodiments, preferably, 0°<θ<10°. For example, in some embodiments, the angle θ may be 4°, but this disclosure is not limited to thereto.

In some embodiments, the laser source used to emit the second laser beam L2 is, for example, a pulsed Nd:YAG laser; the pulse time length of the second laser beam L2 is, for example, in the range of microseconds to milliseconds; and the wavelength of the second laser beam L2 is, for example, 1064 nm or 532 nm; the average power of the second laser beam L2, for example, falls in the range of 20 W˜400 W; the flow rate of the first water column W1, for example, falls in the range of 5 L/hour˜20 L/hour; the water pressure of the first water column W1, for example, falls in the range of 50 bar˜800 bar range; the diameter of the nozzle used to spray the first water column W1 falls within the range of 20 microns˜100 microns, for example; but this disclosure is not limited to thereto.

Referring to FIG. 1C, FIG. 1D and FIG. 4, in some embodiments, before the first water column W1 and the second laser beam L2 are synchronously impacted and irradiated on the first side surface 100c of the object to be modified 100, the object to be modified 100 is fixed between the first transparent substrate G1 and the second transparent substrate G2, wherein the first side surface 100c of the object to be modified 100 is exposed to an air gap AG between the first transparent substrate G1 and the second transparent substrate G2; then, the first water column W1 and the second laser beam L2 are synchronously impacted and irradiated on the first side surface 100c to form the first notch 100c-1 on the first side surface 100c. Referring to FIG. 4, in some embodiments, a method of fixing the object to be modified 100 between the first transparent substrate G1 and the second transparent substrate G2 may include: rendering the first surface 100a and the second surface 100b of the object to be modified 100 be fixed on the first transparent substrate G1 and the second transparent substrate G2 through the first pyrolytic glue layer A1 and the second pyrolytic adhesive layer A2 respectively. In some embodiments, for example, the thickness T1 of the first pyrolytic glue layer A1 and the thickness T2 of the second pyrolytic adhesive layer A2 fall in the range of 20 microns to 60 microns; for example, the adhesion of the first pyrolytic glue layer A1 and the adhesion of the second pyrolytic adhesive layer A2 fall in the range of 0.2 kg/inch˜0.8 kg/inch; the peeling force of the first pyrolytic glue layer A1 and the peeling force of the second pyrolytic adhesive layer A2 fall in the range of 9 gf/inch˜15 gf/inch; for example, the pyrolysis temperature of the first pyrolytic glue layer A1 and the pyrolysis temperature of the second pyrolytic adhesive layer A2 fall within the range of 90°˜130°. However, this disclosure is not limited to thereto. In other embodiments, other tools (such as clamps, vacuum suction cups, etc.) may also be used to fix an object to be modified 100.

Referring to FIG. 1D and FIG. 1E, next, in a condition where the first notch 100c-1 exists, destroy the modification layer 110 to separate a processing object 100′ from the object to be modified 100. It is worth mentioning that since the first notch 100c-1 corresponds to the modification layer 110, the modification layer 110 can be easily destroyed and the processing object 100′ (for example: wafer) can be separated from an object to be modified 100 by applying a little external force. For example, in some embodiments, the processing object 100′ can be easily separated from an object to be modified 100 by applying a small pulling force without the need for heating, cooling or ultrasonic oscillation.

FIG. 5 is a schematic cross-sectional view of a processing object according to an embodiment of this disclosure. Referring to FIG. 1E and FIG. 5, the processing object 100′ includes a base material S. The base material S includes a single crystal material. In some embodiments, the single crystal material may be silicon carbide single crystal material. The base material S has a first surface 100a, a processing surface 100d and a side surface 100c′. The processing surface 100d is located opposite the first surface 100a. The side surface 100c′ is connected to the first surface 100a and the processing surface 100d. The processing surface 100d includes a first processing area 100d-1 and a second processing area 100d-2, the first processing area 100d-1 is closer to the side surface 100c′ than the second processing area 100d-2, and the surface roughness of the first processing area 100d-1 is smaller than the surface roughness of the second processing area 100d-2.

Referring to FIG. 4 and FIG. 5, the first water column W1 and the second laser beam L2 form a water laser, the first processing area 100d-1 of the processing surface 100d of the processing object 100′ corresponds to the water laser processing area R1 where the water laser processes the object to be modified 100. The second processing area 100d-2 of the processing surface 100d of the processing object 100′ corresponds to a modified split area R2 outside the water laser processing area R1 of the object to be modified 100. In other words, the first processing area 100d-1 of the processing surface 100d of the processing object 100′ is formed when the water laser processes the object to be modified 100, and the second processing area 100d-2 of the processing surface 100d of the processing object 100′ is formed when the modification layer 110 is destroyed (that is, during the splitting process). Therefore, the first processing area 100d-1 and the second processing area 100d-2 of the processing surface 100d have different surface roughness.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

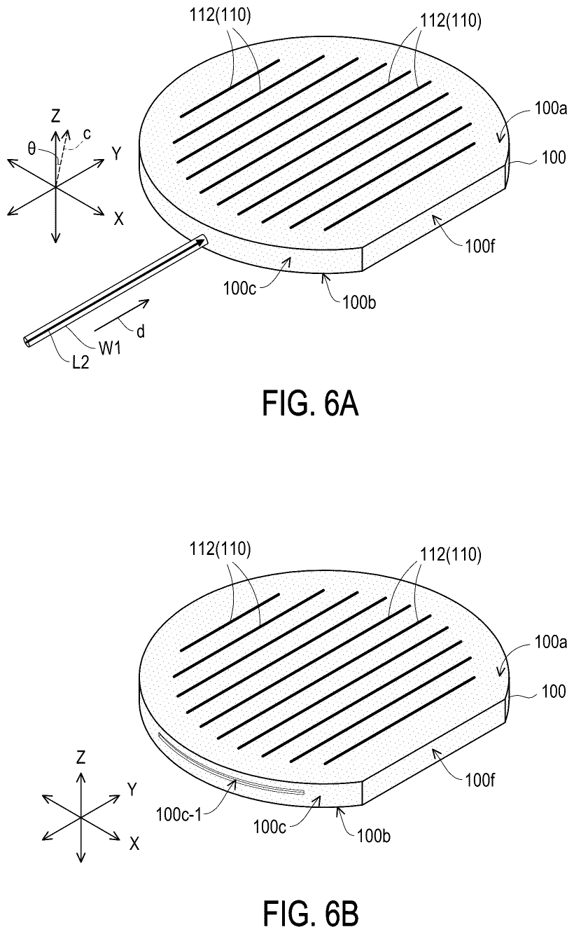

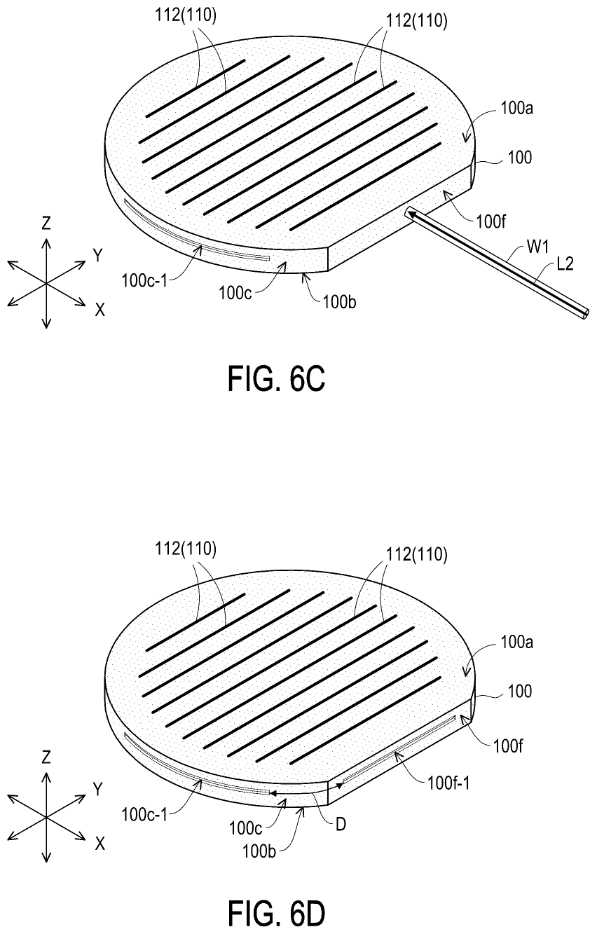

FIG. 6A to FIG. 6D are schematic three-dimensional views of part of the processing flow of a single crystal material according to another embodiment of the present disclosure. The embodiment of FIG. 6A to FIG. 6D is similar to the aforementioned embodiment of FIG. 1A to FIG. 1D, the difference between the two embodiments is that the number of notches formed by the water laser are different.

Referring to FIG. 6A, the object to be modified 100 further includes a second side surface 100f, which is connected to the first surface 100a and the second surface 100b, and is arranged next to the first side surface 100c or opposite to the first side surface 100c. Referring to FIG. 6A to FIG. 6D, in this embodiment, in addition to making the first water column W1 and the second laser beam L2 transmitted in the first water column W1 synchronously impact and irradiate the first side surface 100c of the object to be modified 100 to form the first notch 100c-1, the first water column W1 and the second laser beam L2 transmitted in the first water column W1 may be synchronously impacted and irradiated on the second side surface 100f of the object to be modified 100, so as to form a second notch 100f-1 on the second side surface 100f, wherein the second notch 100f-1 corresponds to the modification layer 110 and separates from the first notch 100c-1 by a distance D.

It should be noted that in the embodiments of FIG. 6A to FIG. 6D, two notches (ie, the first notch 100c-1 and the second notch 100f-1) are formed as an example. However, this disclosure does not limit the number of notches formed by the water laser. In other embodiments not shown, the number of notches formed by water laser may also be more than three. In addition, this disclosure does not restrict that multiple notches formed by the water laser must be separated by a distance D. In other embodiments not shown, the plurality of notches formed by the water laser may be connected to form a circle.

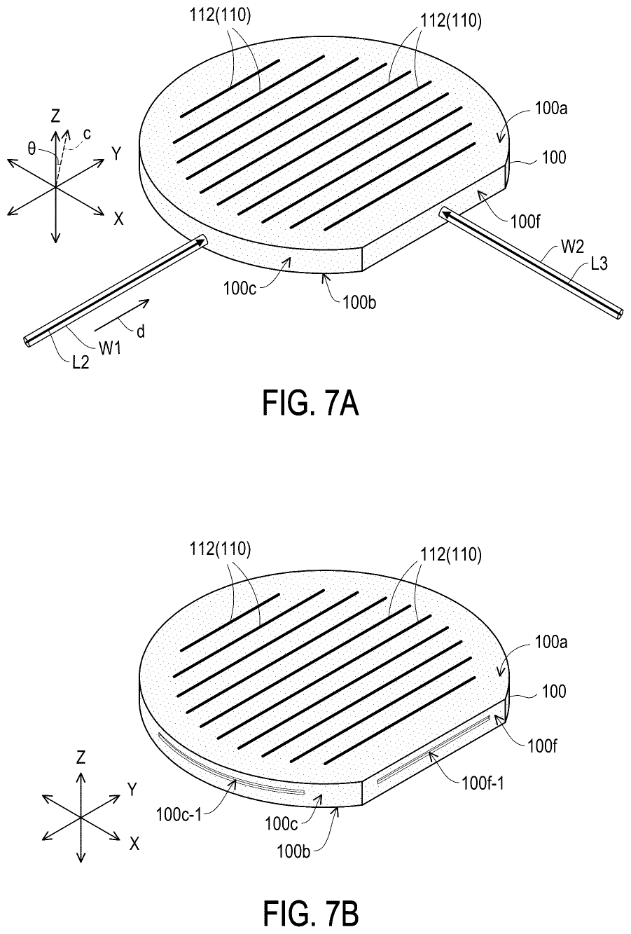

FIG. 7A to FIG. 7B are schematic three-dimensional views of part of the processing flow of a single crystal material according to yet another embodiment of the present disclosure. The embodiments of FIGS. 7A to 7B are similar to the aforementioned embodiments of FIGS. 6A to 6D. The differences between the two embodiments are: in the embodiment of FIG. 6A to FIG. 6D, a single water laser is used to form multiple notches at different times; in the embodiment of FIGS. 7A to 7B, multiple water lasers are used to form multiple notches at the same time.

Referring to FIG. 7A to FIG. 7B, specifically, in this embodiment, in addition to making the first water column W1 and the second laser beam L2 transmitted in the first water column W1 synchronously impact and irradiate the first side surface 100c to form the first notch 100c-1, while the first water column W1 and the second laser beam L2 impact and irradiate the first side surface 100c, the second water column W2 and the third laser beam L3 transmitted in the second water column W2 can synchronously impact and irradiate the second side surface 100f of an object to be modified 100, so as to form the second notch 100f-1 on the second side surface 100f at the same time. In this way, the time required for processing the single crystal material can be reduced.

To sum up, in the processing method of the single crystal material according to one embodiment of this disclosure, first, use the first laser beam to illuminate the first surface of the object to be modified to form the modification layer in the inner portion of the object to be modified; then, the first water column and the second laser beam transmitted in the first water column are used to simultaneously impact and irradiate the first side surface of an object to be modified, so as to form the first notch on the first side surface; finally, with the first notch present, destroy the modification layer to separate the processing object from the object to be modified. In this way, the modification layer can be easily destroyed with a little external force, and the processing object can be separated from the object to be modified. In addition, compared with mechanical cutting, separating the processing object by destroying the modification layer results in less loss of the single crystal material.

What is claimed is:

1. A processing method of single crystal material, comprising:
providing a single crystal material as an object to be modified, wherein the object to be modified has a first surface, a second surface and a first side surface, the first surface is opposite to the second surface, and the first side surface is connected to the first surface and the second surface;
rendering a first laser beam irradiate the first surface of the object to be modified to form a modification layer in an inner portion of the object to be modified, wherein the modification layer is located between the first surface and the second surface; and
rendering a first water column and a second laser beam transmitted in the first water column impact and irradiate the first side surface synchronously to form a first notch on the first side surface, wherein the first notch corresponds to the modification layer.

2. The processing method of single crystal material according to claim 1, further comprising:
In a condition where the first notch exists, destroy the modification layer to separate a processing object from the object to be modified.

3. The processing method of single crystal material according to claim 1, further comprising:
before rendering the first water column and the second laser beam transmitted in the first water column to synchronously impact and irradiate the first side surface, fixing the object to be modified between a first transparent substrate and a second transparent substrate, wherein the first side surface of the object to be modified is exposed in an air gap between the first transparent substrate and the second transparent substrate.

4. The processing method of single crystal material according to claim 3, wherein the first surface and the second surface of the object to be modified are respectively fixed on the first transparent substrate and the second transparent substrate through a first pyrolytic glue layer and a second pyrolytic adhesive layer.

5. The processing method of single crystal material according to claim 4, wherein an adhesion of the first pyrolytic glue layer falls in a range of 0.2 kg/inch˜0.8 kg/inch.

6. The processing method of single crystal material according to claim 4, wherein a peeling force of the first pyrolytic glue layer falls in a range of 9 gf/inch˜15 gf/inch.

7. The processing method of single crystal material according to claim 4, wherein a pyrolysis temperature of the first pyrolytic glue layer falls in the range of 90°˜130°.

8. The processing method of single crystal material according to claim 1, wherein the modification layer is located on a reference plane, a propagation direction of the second laser beam is substantially parallel to the reference plane, a normal direction of the reference plane and a crystal axis direction of the object to be modified form an angle θ, and 0°<θ<90°.

9. The processing method of single crystal material according to claim 1, wherein the object to be modified further comprises a second side surface connected to the first surface and the second surface, and is disposed next to the first side surface or opposite to the first side surface, the processing method of the single crystal material further comprises:
rendering the first water column and the second laser beam transmitted in the first water column impact and irradiate the second side surface synchronously to form a second notch on the second side surface, wherein the second notch corresponds to the modification layer and separates from the first notch by a distance.

10. The processing method of single crystal material according to claim 1, wherein the object to be modified further comprises a second side surface connected to the first surface and the second surface, and is disposed next to the first side surface or opposite to the first side surface, the processing method of the single crystal material further comprises:
rendering a second water column and a third laser beam transmitted in the second water column impact and irradiate the second side surface synchronously to form a second notch on the second side surface, wherein the second notch corresponds to the modification layer and separates from the first notch by a distance.

11. A processing object, comprising:
a base material comprising a single crystal material, wherein the base material has a first surface, a processing surface and a side surface, the processing surface is located opposite the first surface, and the side surface is connected to the first surface and the processing surface;
wherein the processing surface comprises a first processing area and a second processing area, the first processing area is closer to the side surface than the second processing area, and a surface roughness of the first processing area is smaller than a surface roughness of the second processing area.
